(19) United States
(12) Patent Application Publication
(10) Pub. No.: US 2007/0240754 A1
(43) Pub. Date: Oct. 18, 2007

(54) Textured Transparent Film Having Pyramidal Patterns That Can Be Associated With Photovoltaic Cells

(75) Inventors: Patrick Gayout, Villemomble (FR); Dirk Neumann, Herzogenrath (DE); Ingrid Vaverka, Aachen (DE); Ulf Blieske, Monchengladbach (DE)

Correspondence Address: OBLON, SPIVAK, MCCLELLAND, MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 11/579,991

(22) PCT Filed: May 4, 2005
(86) PCT No.: PCT/FR05/50304

§ 371 Date: Dec. 14, 2006

(30) Foreign Application Priority Data
May 10, 2004 (FR) 0450892

(51) Int. Cl. H01L 31/042

(52) U.S. Cl. 136/246

(57) ABSTRACT

A transparent plate includes at least two parallel main borders and has, in relief on at least one of its main surfaces, repetitive pyramidal relief features, each including an apex, a base, and a set of edges that join the apex to the base, and at least one edge of the features being such that its projection in the general plane of the plate is substantially parallel to the two parallel main borders. The plate may be combined with photovoltaic cells so as to enhance the transmission of light to the cells. The plate can easily be produced by hot rolling.

The invention relates to a sheet textured by encrusted geometrical features and to its manufacturing process.

WO 03/046617 teaches the production and the use of textured plates for improving the light transmission of transparent plates integrated into photovoltaic cells, plasma-discharge flat lamps, LCD screens, solar collectors and image projectors. The features of the texture may especially be concave relative to the general plane of the textured face of the plate, that is to say these are encrusted in the base plate. These features may especially be produced by hot rolling a featureless sheet by a roller that impresses the desired features on the plate. Depending on the nature of the features, these may be produced with greater or lesser ease. In particular, it is sometimes observed that the material in the pasty state has a tendency to adhere to the rolling roll, which causes defects visible to the naked eye. The features are then not correctly produced and, in addition, the sheet has a tendency to wrap around the rolling roll. When this happens, it is necessary to stop the manufacture. This sticking effect may be combated by lowering the production rate. Moreover, when the encrusted features of the textured plate are in contact with the ambient air in the final use, these have a tendency to fill up with dust or dirt and have to be cleaned with greater or lesser ease. This is especially the case if the textured plate is used to protect a photovoltaic cell placed outdoors.

The invention provides a solution to the abovementioned problems. The invention relates in particular to a transparent plate comprising at least two parallel main borders and having, in relief on at least one of its main surfaces, repetitive pyramidal relief features (concave or convex features), each comprising an apex, a base and a set of edges that join the apex to the base, and at least one edge of said features being such that its projection in the general plane of the plate is substantially parallel to said two parallel main borders. The word “edge” is used here to denote one of the edges of the pyramid that join the apex to the base. The term “edge” therefore does not denote one of the sides of the base of the pyramid.

The Applicant has observed that it is advantageous for at least one edge as defined above to be judiciously placed. This is because the edge is advantageously in the rolling direction, which is parallel to at least two main borders, since the features on the rolling roll do seem to come more easily into contact with the plate in the pasty state and to separate therefrom without damaging the imprint that has been made therein. In any case, the Applicant has observed that these conditions are more favorable (fewer geometric defects visible to the naked eye) compared with features all of whose edges are oblique to the rolling direction. It seems that the angle that
the straight line located at the intersection, on the one hand, of a plane perpendicular to the general plane of the plate and passing through the apex of the pyramid and, on the other hand, the pyramid itself makes with
the general plane of the plate is particularly important for the quality with which the relief features are formed. It seems in fact that it is preferable for this angle to be small, as in this way the interpenetration of the rolling roll with the plate seems to take place more progressively. It seems that, at each feature, the male pyramid (which depending on the case is on the rolling roll or on the plate to be textured) and the corresponding female pyramid separate from one another more gently and with less of a tendency to stick together. This effect has been observed both for the production of concave pyramids and convex pyramids on the textured plate. This better feature imprinting behavior allows the manufacturing speeds to be increased.

In the case of the production of concave pyramids on the textured plate (by a rolling roll having convex pyramids), an additional effect has been observed. Since the plate is placed in final use so that the two main borders appear vertical when the plate is observed from the front (the general plane of the plate being inclined, for example at 45°, to the horizontal), the judiciously placed edge also appears vertical when viewed from the front and may act as a gutter for the removal of dirt, dust or any liquid, especially cleaning fluid, that has intentionally or unintentionally penetrated the feature, and to do so without it being necessary to move or remove the plate. Consequently, a plate provided with concave pyramids is fouled less over the course of time if these features are oriented according to the invention.

Thus, the invention also relates to the use of a transparent plate having repetitive convex or concave (i.e. encrusted) pyramidal features, each having a number of edges, at least one edge of the features of which appears vertical when the plate is observed from the front and in the lower half of the feature. The edge is a segment joining the center of the feature (or apex of the pyramid) to the periphery of the same feature (or base of the pyramid), said periphery lying in the general plane of the plate. When the plate is provided with concave pyramids, the judiciously placed edge of the features is in their lower part and acts as a gutter for the removal of dirt and other foreign agents flowing along said edge under the effect of their weight. This effect is observed whenever the general plane of the plate is inclined sufficiently to the horizontal.

The plate is generally inclined at an angle ranging from 10° to 90° and more generally 20° to 70° to the horizontal. This angle of inclination represents a choice that may depend on the local sunshine conditions.

The invention also relates to a process for manufacturing a plate according to the invention. According to this process, a plate containing no feature is heated to its softening temperature and subjected to the action of a rolling roll. Preferably, the rolling roll is driven, at the point where the pyramids are formed, with a linear speed less than that of the glass in the cooling zone. The roll has, on its surface, the features to be impressed on the plate. These features appear convex on the roll if it is desired to produce concave features in the plate, and vice versa. This process is applicable to plates made of mineral glass and to thermoplastic polymers, such as polyurethane or polycarbonate or methyl polymethacrylate. The invention therefore relates to a process for manufacturing a plate by rolling, at its deformation temperature, a plate devoid of said features using a roll that impresses the texture on the plate, the rolling direction being parallel to said two main borders and to at least one edge of said features.

In the case of a plate made of silica-based mineral glass, the texturing of the plate may also be carried out during an optional thermal toughening step, just before the glass “freezes”.

Preferably, most of the mass (i.e. at least 98% by weight) of the plate, or even the entire plate, is formed from material(s) having the best possible transparency and preferably having a linear absorption of less than 0.01 mm⁻¹ in that part of the spectrum useful for the application, generally the spectrum ranging from 380 to 1200 nm.

The features join the general plane of the textured face of the plate via a base, said base being able to be inscribed within a circle whose diameter is generally less than 10 mm, or even less than 7 mm. Preferably, the smallest circle that can contain the base of one of said features has a maximum diameter of 5 mm, especially one ranging from 0.001 mm to 5 mm, for example ranging from 1 to 5 mm.

Preferably, the features are contiguous. Features are said to be contiguous when they touch one another in at least part of their base (at the surface and in the general plane of the plate).

The features have the shape of pyramids with a polygonal base, such as a triangular or square or rectangular or hexagonal or octagonal base, and are concave (forming indentations in the mass of the plate) or convex. The pyramids generally have an axis of symmetry passing through their apex. Preferably, the pyramid has two of its edges such that their projection in the general plane of the plate is substantially parallel to the two parallel main borders of the plate. This is especially the case when the pyramid has an axis of symmetry passing through its apex and perpendicular to the general plane of the plate. These two edges appear, to an observer looking at the pyramid with a viewing direction perpendicular to the plate, as being in alignment with one another in order to pass through the entire pyramid.

Preferably, the pyramid has four sides (or faces) and four edges. In this case, it is oriented in the plate in such a way that two of its edges appear vertical and form with both of them a diagonal line of the pyramid for an observer looking at the plate from the front (horizontal view). These two edges appear as being in alignment with one another for an observer looking at the plate from the front, one of the edges being in the lower part of the pyramid, and the other being in the upper part.

It is preferable for any apex half-angle of said pyramid to be less than 70° and preferably to be less than or equal to 60°, for example ranging from 25° to 60°. An apex half-angle is an angle between the axis of symmetry of the pyramid and a straight line contained in the surface of the pyramid and passing through the apex. A pyramid contains a multitude of apex half-angles since the angles between two facing edges are larger than the angles between two facing sides.

The textured plate may especially serve to improve the capture of sunlight in order to increase the luminous flux feeding photoelectric cells. The plate according to the invention even captures highly grazing light rays (with a low angle of incidence). These photoelectric cells may be encapsulated in a resin of the polyvinyl butyral (PVB) or ethylene-vinyl acetate copolymer (EVA) type. This encapsulation is carried out in a known manner in a pressurized autoclave at high temperature (to melt the resin), thereby resulting in a sheet of resin in which the cells are imprisoned. The textured plate is then juxtaposed with this sheet in order to capture the light (with the texture on the side facing the ambient air) and to deliver the light to the cells in the sheet. On the other side of the sheet containing the cells there may be a glass plate. It is possible to combine all these components in a single autoclave step. Such a complex structure may serve both as a solar energy sensor and as an antinoise wall. Its antinoise effectiveness is even better when the resin used is of the “acoustic” type, that is to say one that attenuates noise.

Thus, the invention also relates to an assembly comprising a plate according to the invention and at least one photoelectric cell, the texture of the plate being in contact with the ambient air (i.e. directed toward the outside), the plate and the cell being placed parallel to each other. In particular, the photoelectric cell may be encapsulated in a resin, which may be a PVB. In addition, this PVB may attenuate noise.

The invention also relates to a device for converting light energy into electrical energy via at least one photoelectric cell, comprising a plate/photoelectric cell assembly according to the invention, at least one edge of the features appearing vertical when the plate is observed from the front and in the lower half of the feature, said texture being on the side facing the incident light and said plate being inclined to the horizontal at an angle ranging from 10° to 90°.

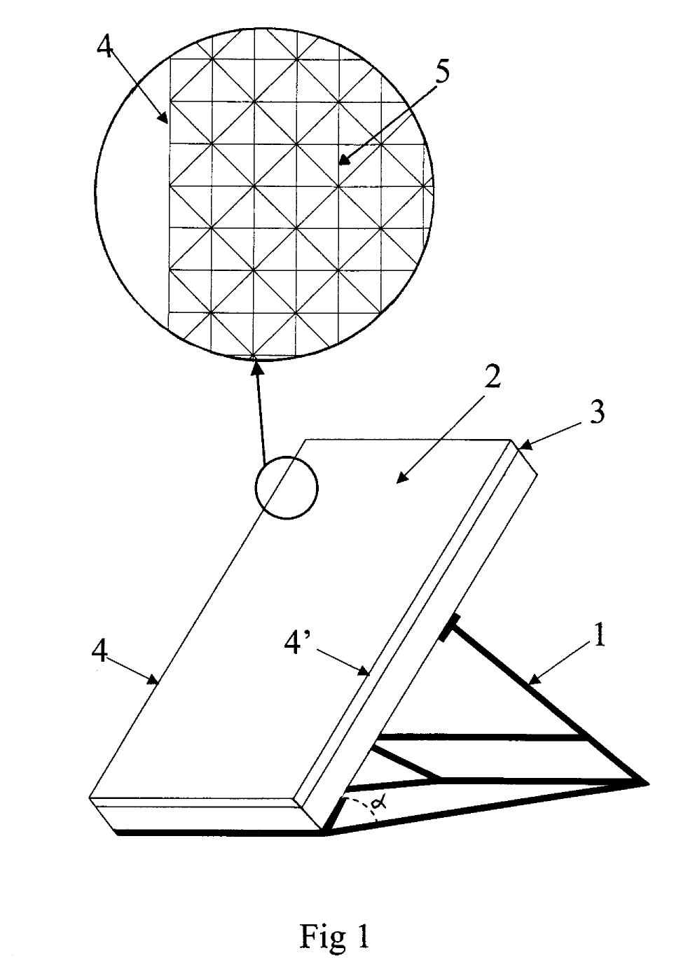

FIG. 1 shows an assembly for converting natural sunlight into electrical energy. A metal frame 1 keeps a light-receiving assembly in an inclined position at an angle α to the horizontal, said assembly comprising a textured plate 2 made of transparent mineral glass placed on a plane of photovoltaic cells 3. The textured plate has two parallel borders 4 and 4′. For an observer looking at the assembly from the front, these two borders 4 and 4′ appear vertical. The textured plate increases the light intensity transmitted to the cells compared with an identical transparent plate but devoid of any texture. The electrical energy delivered is therefore greater owing to the presence of the texture. The relief of this texture is on the side facing the ambient air, that is to say the side that receives the light. The features are contiguous and here are a succession of repetitive pyramidal features that are concave (or encrusted in the sheet). Each pyramid has four sides and four edges that come together at the apex. These pyramids are oriented obliquely to the borders 4 and 4′ of the plate (the sides of the base make an angle of 45° with the borders 4 and 4′). Thanks to this orientation, at least one edge of each pyramid appears vertical for an observer looking at the assembly from the front and lies in the lower half of the pyramid (here a concave pyramid). Thanks to this situation, this edge may act as a gutter for the removal of any foreign body in the pyramid.

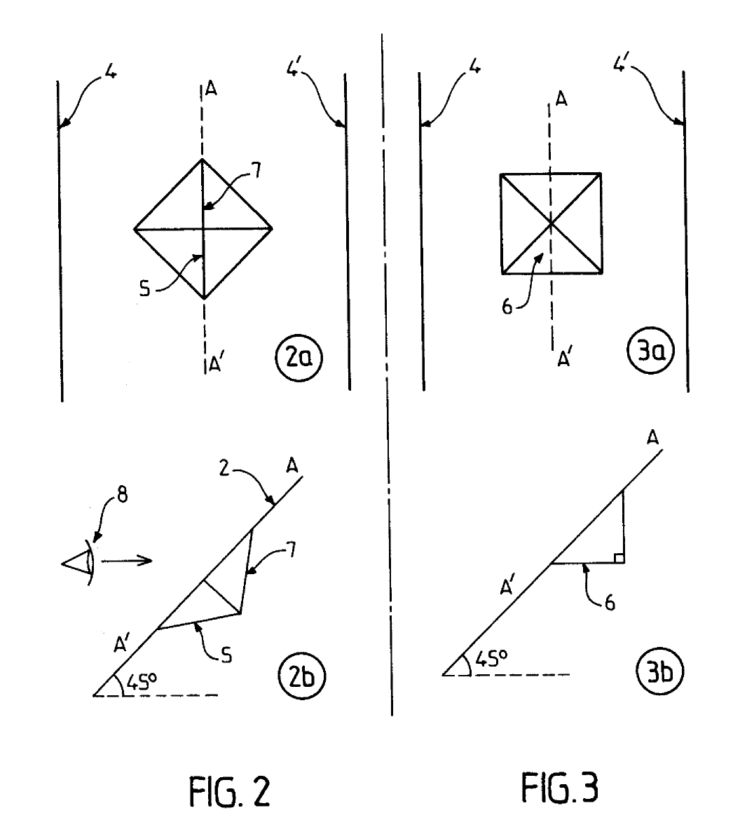

FIGS. 2 and 3 provide by way of indication an explanation of the gutter effect conferred by the edge 5 on the concave feature. FIG. 2a shows a concave pyramidal feature oriented according to the invention, that is to say in such a way that an edge 5 appears vertical for an observer looking at the plate from the front and is parallel to the two main borders 4 and 4′ of the plate. FIG. 2b shows the feature of FIG. 2a seen in cross section on AA′, in the plate 2 inclined at 45° to the horizontal. The line AA′ of FIG. 2b lies in the general plane of the plate, the features being produced as indentations relative to this plane. It should be noted that the edge 5 is inclined downward in the direction of easy removal of any foreign body present in the pyramid. It is located in the lower part of the pyramid. Owing to the geometry of the pyramid, another edge 7 located in the upper part of the feature lies along the extension of the edge 5 in such a way that, for an observer looking at the plate from the front (with a horizontal view represented by the eye 8), the edges 5 and 7 are in alignment with one another and appear to form a vertical line as shown in FIG. 2a. The projection of the edge 5 in the general plane of the plate lies along the line AA′ of FIG. 2b and this projection is parallel to the two parallel main borders 4 and 4′. For comparison, FIG. 3 shows exactly the same pyramid except that it is not oriented obliquely to the general direction of the plate. In this case, no edge appears vertical to an observer looking at the plate from the front. No edge appears parallel to the borders 4 and 4′ for a front observer. A foreign body in the pyramid has to be removed by sliding over the lower side 6. However, the sectional view in the vertical plane AA′ (FIG. 3b) shows that the side 6 is much less inclined (it is even approximately horizontal) than the edge 5 in the case of FIG. 2. This is why the “oblique pyramid” configuration (i.e. oblique to the edges 4 and 4′ of the plate) according to the invention as shown in FIG. 2 is more favorable for the removal of foreign bodies in the pyramid than the configuration shown in FIG. 3. This configuration is more favorable for rainwater to flow away and for the plate to be cleaned. This configuration is also more favorable to the manufacture of the plate by rolling, perhaps owing to a behavior analogy between a liquid flowing out of the feature and the displacement of the solid impression in the pyramid during manufacture. It may be seen that the angle that
the straight line located at the intersection, on the one hand, of a plane perpendicular to the general plane of the plate and passing through the apex of the pyramid and, on the other hand, the pyramid itself makes with
the general plane of the plate is the angle between the edge 5 (or 6 in the case of FIG. 3b) and the general plane of the plate merging in FIGS. 2b and 3b with the line AA′. This angle is appreciably smaller in the case of an orientation of the pyramid according to the invention (compare edge 5 in FIG. 2b with edge 6 in FIG. 3b). This smaller angle is favorable for the quality with which the relief features are formed.

Of course, the borders 4 and 4′ have been shown so as to indicate their orientation, but the distance between 4 and 4′ is much greater than it appears in FIGS. 2a and 3a (relative to the size of the feature drawn), since between these borders there are numerous features (generally several tens of features).

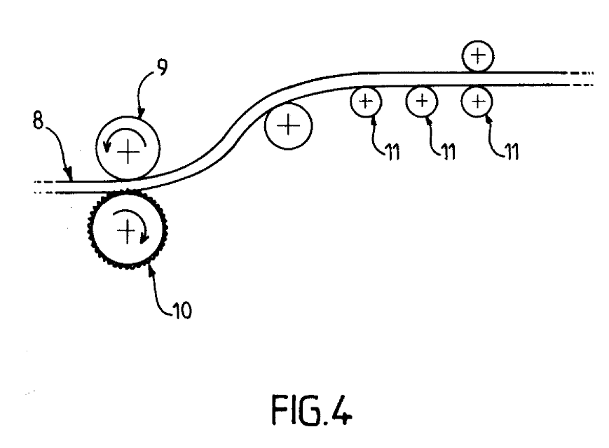

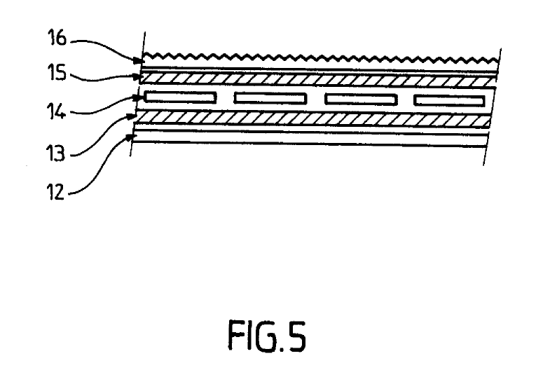

FIG. 4 shows a manufacturing process according to the invention. Everything shown in this figure is in a furnace (not shown) at 1000° C. The flat glass 8 in the pasty state is calendered between two rolls 9 and 10, the latter roll (10) having convex pyramids on its surface. Since the glass is pressed between these two rolls, it takes on a texture consisting of concave pyramids on its lower face. The glass is then taken over a bed of rolls 11 before being cooled. The speed of the glass ribbon is 3 m/min. The linear speed of the texturing roll 10 is about 20% lower than that of the glass ribbon, i.e. about 2.4 m/min. The linear speed of all the other rolls is identical to the speed of the ribbon. The ribbon is in fact hauled off to the outside of the furnace by other rolls.

To give an example, in the case of manufacture corresponding to that of FIG. 4, the pyramids having a square base of 2.4×2.4 mm and a depth of 1.1 mm, it has been found that an orientation of the pyramids according to the invention (as shown in FIG. 2) makes it possible to achieve a yield of 80%, whereas when the pyramids are oriented as in FIG. 3 the yield is only 30%. This yield is the manufacturing yield. This is because malformation of the pyramids also occurs owing to the fact that the glass ribbon, instead of following its normal path toward the rolls 11, has a tendency to wrap around the roll 10, requiring the production to be stopped.

FIG. 5 shows a stack of sheets and plates before it passes into an autoclave. The plate 12 is a textureless glass of the Planilux type, on which a first PVB sheet is placed. The photoelectric cells 14 are placed between the two PVB sheets 13 and 15. Over the whole assembly is the textured mineral glass plate according to the invention, the texture of which is on the side facing the ambient air. Passage through the autoclave will cause the cells to be encapsulated in the PVB and will make the PVB adhere to the glass plates.

According to a variant of the invention, it may be judicious for the features on the plate to be functionalized.

Thus, thin films are deposited on the surface that are intended to give a particular property such as, for example, that consisting in allowing the substrate to remain as clean as possible, whatever the environmental attack, that is to say with the aim of maintaining surface and appearance properties over time, and in particular allowing the cleaning operations to be spaced apart, while succeeding in removing any soiling matter as it is being progressively deposited on the surface of the substrate, especially soiling matter of organic origin, such as fingerprints or volatile organic compounds present in the atmosphere, or even soiling matter of the pollution dust or soot type.

Now, it is known that certain metal-oxide-based semiconductor materials exist that are capable, under the effect of radiation of suitable wavelength, to initiate radical reactions that cause organic compounds to oxidize. These are generally called “photocatalytic” or “photoreactive” materials.

In the field of substrates having a glazing function, it is known to use photocatalytic coatings on the substrate that have a pronounced “antisoiling” effect and can be manufactured on an industrial scale. These photocatalytic coatings generally include at least partly crystallized titanium oxide, incorporated into the coating in the form of particles, especially with a size of between a few (3 or 4) nanometers and 100 nm, preferably around 50 nm, these being essentially crystallized in anatase or anatase/rutile form.

Titanium oxide falls within semiconductors that, under the action of light in the visible or ultraviolet range, degrade organic compounds deposited on their surface.

Thus, according to a first exemplary embodiment, the coating with a photocatalytic property results from a solution based on TiO₂ nanoparticles and a mesoporous silica (SiO₂) binder.

According to a second exemplary embodiment, the coating with a photocatalytic property results from a solution based on TiO₂ nanoparticles and an unstructured silica (SiO₂) binder.

Furthermore, whatever the embodiment of the photocatalytic coating, as regards the titanium oxide particles the choice falls on titanium oxide that is at least partly crystallized because it has been shown that this is much more efficient in terms of photocatalytic property than amorphous titanium oxide. Preferably, it is crystallized in anatase form, in rutile form or in the form of an anatase/rutile mixture.

The manufacture of the coating is carried out so that the crystallized titanium oxide that it contains is in the form of “crystallites”, that is to say single crystals, having a mean size of between 0.5 and 100 nm, preferably 3 to 60 nm. This is because it is within this size range that the titanium oxide appears to have the optimum photocatalytic effect, probably because the crystallites of this size develop a large active surface area.

The coating with a photocatalytic property may also include, apart from titanium oxide, at least one other type of mineral material, especially in the form of an amorphous or partly crystallized oxide, for example silicon oxide (or a mixture of silicon oxides), titanium oxide, tin oxide, zirconium oxide or aluminum oxide. This mineral material may also contribute to the photocatalytic effect of the crystallized titanium oxide, by itself having a certain photocatalytic effect, even though small compared with that of crystallized TiO₂, which is the case for amorphous or partly crystallized titanium oxide.

It is also possible to increase the number of charge carriers by doping the crystal lattice with titanium oxide, inserting thereinto at least one of the following metallic elements: niobium, tantalum, iron, bismuth, cobalt, nickel, copper, ruthenium, cerium and molybdenum.

This doping may also be carried out by doping only the surface of the titanium oxide or the entire coating, surface doping being carried out by covering at least some of the coating with layers of oxides or metal salts, the metal being chosen from iron, copper, ruthenium, cerium, molybdenum, vanadium and bismuth.

Finally, the photocatalytic effect may be enhanced by increasing the yield and/or rate of the photocatalytic reactions, while covering the titanium oxide or at least part of the coating that incorporates it with a noble metal in the form of a thin film of the platinum, rhodium or silver type.

The coating with a photocatalytic property also has an external surface of pronounced hydrophilicity and/or oleophilicity, especially in the case in which the binder is a mineral binder, thereby providing two not insignificant advantages: hydrophilicity allows perfect wetting by water, which can be deposited on the coating, thus making cleaning easier. In addition to hydrophilicity, it may also exhibit oleophilicity, allowing the “wetting” of organic soiling matter which, as in the case of water, then tends to be deposited on the coating in the form of a continuous film that is less visible than highly localized “stains”. What is thus obtained is an “organic antisoiling” effect that takes place in two stages. First, as soon as the soiling matter is deposited on the coating, it already becomes barely visible and then it progressively disappears by photocatalytically initiated radical degradation.

The thickness of the coating according to the invention can vary between a few nanometers and a few microns, typically between 50 nm and 10 μm.

In fact, the choice of thickness may depend on various parameters, especially on the envisaged application of the substrate or on the size of the TiO₂ crystallites in the coating. The coating may also be chosen to have a relatively smooth surface—a slight surface roughness may in fact be advantageous if it allows a larger photocatalytically active surface area to develop. However, too pronounced a roughness may be prejudicial, by promoting the incrustation and accumulation of soiling matter.

1-12. (canceled)

13. An assembly comprising:
a transparent plate comprising at least two parallel main borders and having, in relief on at least one of its main surfaces, repetitive pyramidal relief features, each comprising an apex, a base, and a set of edges that join the apex to the base, and
wherein at least one edge of the features is such that its projection in a general plane of the plate is substantially parallel to the two parallel main borders and at least one photoelectric cell, a texture of the plate being in contact with ambient air, the plate and the cell being placed parallel to each other.

14. The assembly as claimed in claim 13, wherein the photoelectric cell is encapsulated in a resin.

15. The assembly as claimed in claim 14, wherein the resin is a PVB.

16. A transparent plate to be used in an assembly as claimed in claim 13, comprising:
at least two parallel main borders and having, in relief on at least one of its main surfaces, repetitive pyramidal relief features, each comprising an apex, a base, and a set of edges that join the apex to the base,
wherein at least two edges of the features is such that their projection in the general plane of the plate is substantially parallel to the two parallel main borders.

17. The plate as claimed in claim 16, wherein the pyramids are concave.

18. The plate as claimed in claim 16, wherein the base of the pyramids may be inscribed within a circle whose diameter is less than 10 mm.

19. The plate as claimed in claim 16, wherein the pyramids have four faces.

20. The plate as claimed in claim 16, wherein the features are coated with a coating having photocatalytic properties.

21. A device for converting light energy into electrical energy via at least one photoelectric cell, comprising:
an assembly as claimed in claim 13, at least one edge of the features appearing vertical when the plate is observed from the front and in the lower half of the feature, the texture being on a side facing the incident light and the plate being inclined to the horizontal at an angle ranging from 10°to 90°.

22. A process for manufacturing a plate as claimed in claim 16, by rolling, at its deformation temperature, a plate devoid of the features using a roll that impresses the texture on the plate, the rolling direction being parallel to the two main borders and to at least one edge of the features.

23. The process as claimed in claim 22, wherein the features on the plate are concave.

24. The process as claimed in claim 22, wherein the features on the plate are convex.
